(19) United States
(12) Patent Application Publication
(10) Pub. No.: US 2014/0070295 A1
(43) Pub. Date: Mar. 13, 2014

(54) NONVOLATILE SEMICONDUCTOR MEMORY DEVICE

(71) Applicant: KABUSHIKI KAISHA TOSHIBA, Tokyo (JP)

(72) Inventors: Ryo FUKUDA, Yokohama-shi (JP); Takeshi Hioka, Yokohama-shi (JP); Hiroyasu Tanaka, Yokkaichi-shi (JP)

(73) Assignee: KABUSHIKI KAISHA TOSHIBA, Tokyo (JP)

(21) Appl. No.: 13/837,206

(22) Filed: Mar. 15, 2013

(30) Foreign Application Priority Data
Sep. 7, 2012 (JP) 2012-196830

(51) Int. Cl. H01L 27/108

(52) U.S. Cl. CPC H01L 27/10805
USPC 257/306

(57) ABSTRACT

A semiconductor memory device includes a capacitor.

The capacitor includes: a first conductive layer functioning as a first electrode, the first conductive layer including a first portion; a second conductive layer functioning as the first electrode, the second conductive layer including a second portion, the second portion and the first portion being arranged in a first direction parallel to the semiconductor substrate; a third conductive layer functioning as a second electrode, the third conductive layer including a third portion; and a fourth conductive layer functioning as the second electrode, the fourth conductive layer including a fourth portion, the fourth portion and the third portion being arranged in the first direction, both the fourth portion and the third portion being arranged in a second direction away from the second portion and the first portion, the second direction being parallel to the semiconductor substrate and being orthogonal to the first direction.

### CROSS REFERENCE TO RELATED APPLICATIONS

This application is based on and claims the benefit of priority from prior Japanese Patent Application No. 2012-196830, filed on Sep. 7, 2012, the entire contents of which are incorporated herein by reference.

### FIELD

The present embodiments relate to a nonvolatile semiconductor memory device.

### BACKGROUND

In recent years, numerous semiconductor memory devices having memory cells disposed three-dimensionally have been proposed in order to increase the level of integration of memory.

Such semiconductor memory devices also require a capacitor, similarly to semiconductor memory devices of conventional planar structure. The capacitor is used in boosting of power supply voltage or employed as a protection element. A known technology for forming a large capacity capacitor in a small area forms the capacitor by processing a stacked wiring line structure similar to a stacked word line structure in a memory cell array.

### BRIEF DESCRIPTION OF THE DRAWINGS

FIG. 1 is a block diagram of a nonvolatile semiconductor memory device according to a first embodiment.

FIG. 2 is an equivalent circuit diagram describing a specific configuration of a memory block MB.

FIG. 3 is a perspective view describing a stacking structure of a memory cell array 11.

FIG. 4 is a cross-sectional view describing the stacking structure of the memory cell array 11.

FIG. 5 is a cross-sectional view describing a specific structure of a capacitor CAP11.

FIG. 6 is a plan view describing a specific structure of the capacitor CAP11 and a contact formation portion CN.

FIG. 7 is a perspective view describing the specific structure of the capacitor CAP11 and the contact formation portion CN.

FIG. 8 is a process diagram describing a manufacturing process of the capacitor CAP11 and the contact formation portion CN.

FIG. 9 is a process diagram describing a manufacturing process of the capacitor CAP11 and the contact formation portion CN.

FIG. 10 is a process diagram describing a manufacturing process of the capacitor CAP11 and the contact formation portion CN.

FIG. 11 is a cross-sectional view describing a specific structure of a capacitor CAP11 and a contact formation portion CN according to a second embodiment.

FIG. 12 is a plan view describing the specific structure of the capacitor CAP11 and the contact formation portion CN according to the second embodiment.

FIG. 13 is a perspective view describing the specific structure of the capacitor CAP11 and the contact formation portion CN according to the second embodiment.

FIG. 14 is a plan view describing a layout of a memory block MB, a capacitor CAP11, and a contact formation portion CN according to a third embodiment.

FIG. 15 is a plan view describing a layout of a memory block MB, a capacitor CAP11, and a contact formation portion CN according to a fourth embodiment.

FIG. 16 is a plan view describing a layout of a memory block MB, a capacitor CAP11, and a contact formation portion CN according to a fifth embodiment.

FIG. 17 is a plan view showing a modified example of the fifth embodiment.

### DETAILED DESCRIPTION

A nonvolatile semiconductor memory device according to the present embodiment comprises: a semiconductor substrate; a memory cell array including a plurality of memory cells stacked; and a capacitor.

The capacitor includes: a first conductive layer functioning as a first electrode, the first conductive layer including a first portion; a second conductive layer functioning as the first electrode, the second conductive layer including a second portion, the second portion and the first portion being arranged in a first direction parallel to the semiconductor substrate; a third conductive layer functioning as a second electrode, the third conductive layer including a third portion; and a fourth conductive layer functioning as the second electrode, the fourth conductive layer including a fourth portion, the fourth portion and the third portion being arranged in the first direction, both the fourth portion and the third portion being arranged in a second direction away from both the second portion and the first portion, the second direction being parallel to the semiconductor substrate and being orthogonal to the first direction. The capacitor also includes a first contact connected to the first portion; a second contact connected to the second portion; a third contact connected to the third portion; and a fourth contact connected to the fourth portion.

A nonvolatile semiconductor memory device according to the present embodiment comprises: a memory cell array provided above a semiconductor substrate and configured having memory transistors arranged three-dimensionally therein; and a capacitor provided above the semiconductor substrate. The capacitor includes a plurality of first conductive layers. The plurality of first conductive layers are formed on the semiconductor substrate and function as a first electrode and a second electrode of the capacitor. A contact formation portion is configured having ends of these plurality of first conductive layers formed in a stepped shape, the stepped shape being arranged in a matrix in a first direction and a second direction, the second direction being orthogonal to the first direction. A contact is formed extending from the contact formation portion. A wiring line portion is connected to the contact and extends with the first direction as a long direction. The contact formation portion is formed such that the first conductive layer functioning as the first electrode is aligned in the first direction, and such that the first conductive layer functioning as the second electrode is aligned in the first direction.

A nonvolatile semiconductor memory device according to embodiments is described below with reference to the drawings.

### First Embodiment

### Schematic Configuration

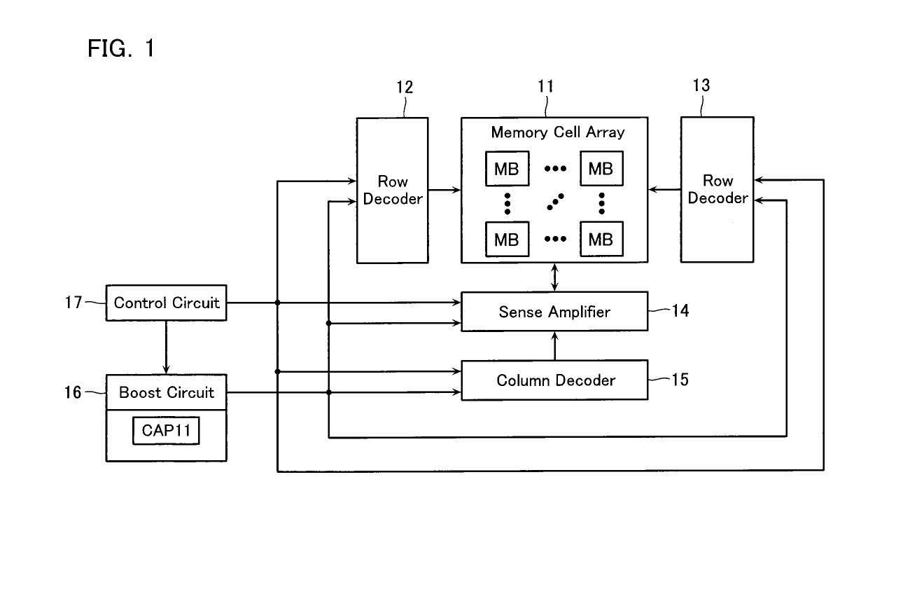

A configuration of a nonvolatile semiconductor memory device according to a first embodiment is described below. FIG. 1 is a block diagram of the nonvolatile semiconductor memory device according to the first embodiment.

As shown in FIG. 1, the nonvolatile semiconductor memory device according to the first embodiment includes a memory cell array 11, row decoders 12 and 13, a sense amplifier 14, a column decoder 15, a boost circuit 16, and a control circuit 17. Peripheral circuits formed surrounding the memory cell array 11, for example, the boost circuit 16, comprise a capacitor CAP11.

The memory cell array 11 is configured from a plurality of memory blocks MB. Each of the memory blocks MB is configured having a plurality of memory transistors MTr arranged three-dimensionally therein. Each of the memory transistors MTr is configured to store data in a nonvolatile manner. The memory block MB configures a smallest erase unit of batch erase when executing a data erase operation.

As shown in FIG. 1, the row decoders 12 and 13 function to decode a row address signal and select a word line. The sense amplifier 14 reads data from the memory cell array 11. The column decoder 15 functions to decode a column address signal and select a bit line.

The boost circuit 16 generates a high voltage required in a write operation, erase operation, and so on, and supplies this high voltage to the row decoders 12 and 13, the sense amplifier 14, and the column decoder 15. The control circuit 17 controls the row decoders 12 and 13, the sense amplifier 14, the column decoder 15, and the boost circuit 16.

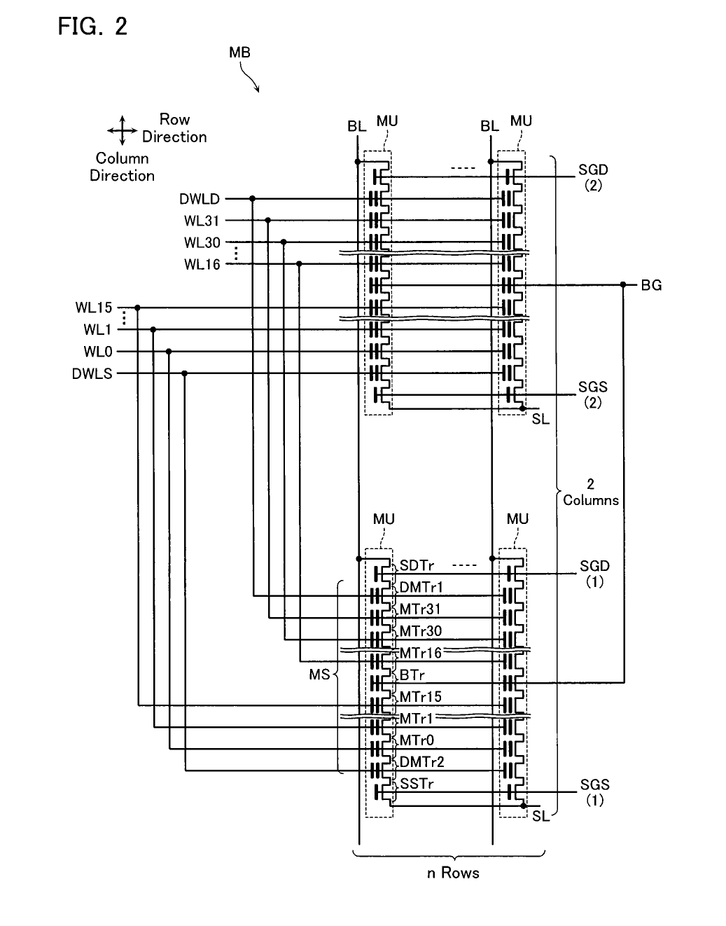

Next, a specific configuration of the memory block MB is described with reference to FIG. 2. As shown in FIG. 2, the memory block MB includes a plurality of bit lines BL, a plurality of source lines SL, and a plurality of memory units MU connected to these bit lines BL and source lines SL.

The memory block MB includes memory units MU arranged in a matrix of n rows by 2 columns. The configuration of n rows by 2 columns is merely an example, and the present embodiment is not limited to this configuration.

One end of the memory unit MU is connected to the bit line BL, and the other end of the memory unit MU is connected to the source line SL. A plurality of bit lines BL extend in a column direction with a certain pitch in a row direction.

The memory unit MU includes a memory string MS, a source side select transistor SSTr, and a drain side select transistor SDTr.

As shown in FIG. 2, the memory string MS includes, connected in series, memory transistors MTr0˜MTr31 (memory cells), a back gate transistor BTr, and dummy memory transistors DMTr1 and DMTr2 (dummy memory cells). The dummy memory transistors DMTr1 and DMTr2 are transistors that have a structure identical to that of the memory cells but are not used in data storage. The present embodiment described below explains an example where the memory string MS includes dummy memory transistors, but the present invention may be applied also to a nonvolatile semiconductor memory device having a memory cell array that does not include such dummy memory transistors.

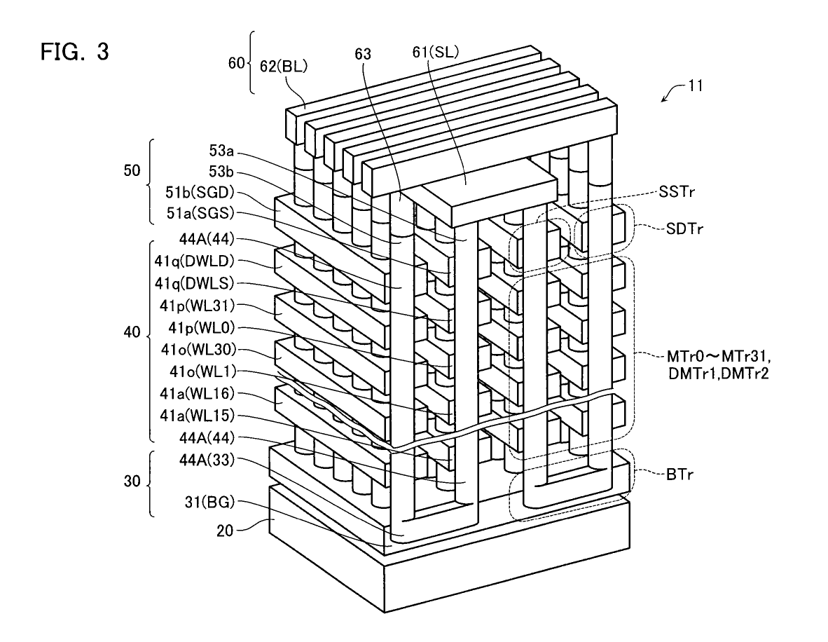

The memory transistors MTr0˜MTr15 and the dummy memory transistor DMTr2 are connected in series with each other, and the memory transistors MTr16˜MTr31 and the dummy memory transistor DMTr1 are connected in series with each other. The back gate transistor BTr is connected between the memory transistor MTr15 and the memory transistor MTr16. Note that as shown in FIG. 3 which is described later, the memory transistors MTr0˜MTr31 and the dummy memory transistors DMTr1 and DMTr2 are arranged three-dimensionally in the row direction, the column direction, and a stacking direction (direction substantively perpendicular to the semiconductor substrate).

The memory transistors MTr0˜MTr31 retain data by storing a charge in a charge storage layer of the memory transistors MTr0˜MTr31. The back gate transistor BTr and the dummy memory transistors DMTr1 and DMTr2 are rendered in a conductive state at least in the case where the memory string MS is selected as a target of an operation.

Commonly connected to gates of the memory transistors MTr0˜MTr31 and the dummy memory transistors DMTr1 and DMTr2 disposed in the matrix of n rows by 2 columns in the memory block MB are word lines WL0˜WL31 and dummy word lines DWLD and DWLS, respectively. Commonly connected to gates of the n rows by 2 columns of back gate transistors BTr is a single back gate line BG.

The drain of the source side select transistor SSTr is connected to the source of the memory string MS. The source of the source side select transistor SSTr is connected to the source line SL. Commonly connected to gates of the n source side select transistors SSTr arranged in a line in the row direction in the memory block MB is a single source side select gate line SGS (1) or SGS (2). Note that below, the source side select gate lines SGS (1) and SGS (2) are also sometimes collectively referred to as source side select gate line SGS, without distinction.

The source of the drain side select transistor SDTr is connected to the drain of the memory string MS. The drain of the drain side select transistor SDTr is connected to the bit line BL. Commonly connected to gates of the n drain side select transistors SDTr arranged in a line in the row direction in each of the memory blocks MB is a drain side select gate line SGD(1) or SGD(2). Note that below, the drain side select gate lines SGD (1) and SGD(2) are also sometimes collectively referred to as drain side select gate line SGD, without distinction.

[Stacking Structure of Memory Cell Array 11]

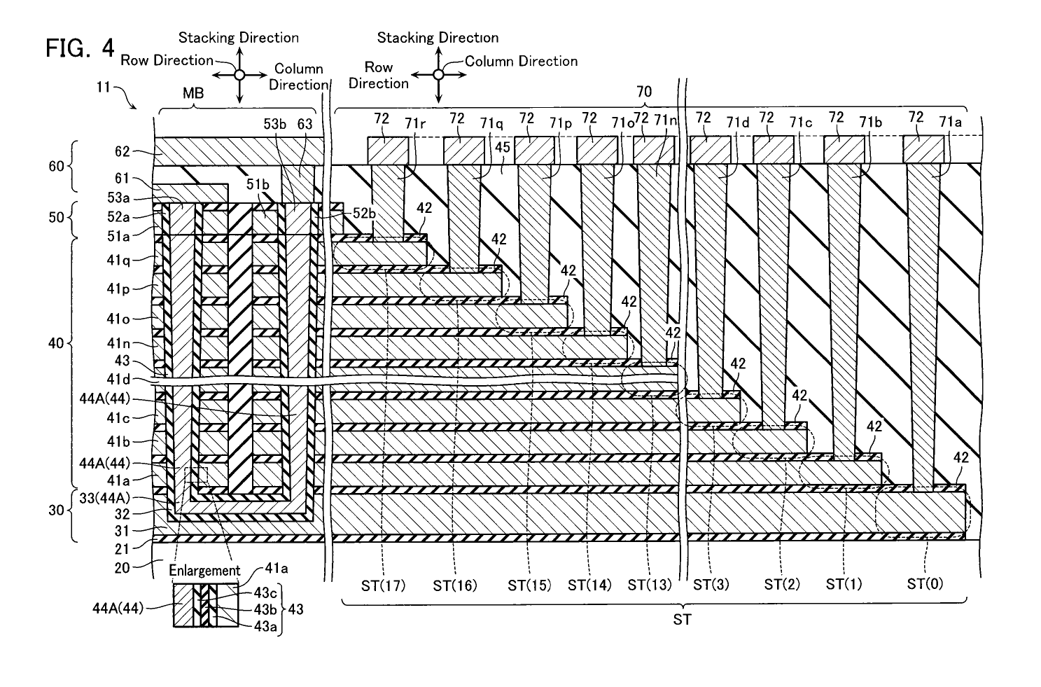

Next, a stacking structure of the memory cell array 11 is described with reference to FIGS. 3 and 4. As shown in FIGS. 3 and 4, the memory cell array 11 includes, stacked sequentially on a semiconductor substrate 20, a back gate layer 30, a memory layer 40, a select transistor layer 50, and a wiring layer 60. The back gate layer 30 functions as the back gate transistor BTr. The memory layer 40 functions as the memory transistors MTr0˜MTr31 and the dummy memory transistors DMTr1 and DMTr2. The select transistor layer 50 functions as the drain side select transistor SDTr and the source side select transistor SSTr. The wiring layer 60 functions as the source line SL and the bit line BL.

As shown in FIGS. 3 and 4, the back gate layer 30 includes a back gate conductive layer 31 formed on an interlayer insulating film 21. The back gate conductive layer 31 functions as the back gate line BG and the gate of the back gate transistor BTr. The back gate conductive layer 31 extends two-dimensionally in a plate shape in the row direction and the column direction parallel to the semiconductor substrate 20. The back gate conductive layer 31 is configured by, for example, polysilicon (poly-Si).

As shown in FIG. 4, the back gate layer 30 includes a memory gate insulating layer 32 and a semiconductor layer 33. The semiconductor layer 33 functions as a body (channel) of the back gate transistor BTr.

The memory gate insulating layer 32 contacts a side surface of the back gate conductive layer 31. The semiconductor layer 33, along with the back gate conductive layer 31, sandwiches the memory gate insulating layer 32.

The semiconductor layer 33 functions as a body (channel) of the back gate transistor BTr. The semiconductor layer 33 is formed digging out the back gate conductive layer 31. When viewed from an upper surface, the semiconductor layer 33 is formed in a substantially rectangular shape having the column direction as a long direction. The semiconductor layers 33 in one memory block MB are formed in a matrix in the TOW direction and the column direction. The semiconductor layer 33 is configured by polysilicon (poly-Si).

Expressing the above-described configuration of the back gate layer 30 in other words, the back gate conductive layer 31 surrounds side surfaces and a lower surface of the semiconductor layer 33 via the memory gate insulating layer 32.

As shown in FIGS. 3 and 4, the memory layer 40 is formed in a layer above the back gate layer 30. The memory layer 40 includes 17 layers of word line conductive layers 41a˜41q and an interlayer insulating layer 42 sandwiched between the word line conductive layers 41a˜41q.

The word line conductive layer 41a functions as the word line WL15 and the gate of the memory transistor MTr15. Moreover, the word line conductive layer 41a functions also as the word line WL16 and the gate of the memory transistor MTr16. Similarly, the word line conductive layers 41b-41p function as the word lines WL14˜WL0 and the gates of the memory transistors MTr14˜MTr0, respectively. Moreover, the word line conductive layers 41b-41p function also as the word lines WL17˜WL31 and the gates of the memory transistors MTr17˜MTr31, respectively. In addition, the word line conductive layer 41q functions as the dummy word lines DWLD and DWLS and the dummy memory transistors DMTr1 and DMTr2.

The word line conductive layers 41a˜41q are formed sandwiching the interlayer insulating layer 42 between them above and below. The word line conductive layers 41a˜41q extend having the row direction (direction perpendicular to plane of paper in FIG. 3) as a long direction and with a pitch in the column direction. The word line conductive layers 41a˜41q are configured by, for example, polysilicon (poly-Si).

The interlayer insulating layer 42 is provided between the word line conductive layers 41a˜41q above and below the word line conductive layers 41a˜41q. The interlayer insulating layer 42 is configured by, for example, silicon oxide (SiO₂).

As shown in FIG. 4, the memory layer 40 includes a memory gate insulating layer 43 and a columnar semiconductor layer 44. The columnar semiconductor layer 44 functions as a body (channel) of the memory transistors MTr0˜MTr31 and the dummy memory transistors DMTr1 and DMTr2.

The memory gate insulating layer 43 contacts a side surface of the word line conductive layers 41a˜41q. The memory gate insulating layer 43 is formed continuously in an integrated manner with the previously mentioned memory gate insulating layer 32. The memory gate insulating layer 43 includes, from a side of the side surface of the word line conductive layers 41a˜41q to a columnar semiconductor layer 44 side, a block insulating layer 43a, a charge storage layer 43b, and a tunnel insulating layer 43c. The charge storage layer 43b is configured capable of storing a charge.

The block insulating layer 43a is formed with a certain thickness on a side wall of the word line conductive layers 41a˜41q. The charge storage layer 43b is formed with a certain thickness on a side wall of the block insulating layer 43a. The tunnel insulating layer 43c is formed with a certain thickness on a side wall of the charge storage layer 43b. The block insulating layer 43a and the tunnel insulating layer 43c are configured by silicon oxide (SiO₂). The charge storage layer 43b is configured by silicon nitride (SiN).

A side surface of the columnar semiconductor layer 44, along with the word line conductive layers 41a˜41q, sandwiches the memory gate insulating layer 43. The columnar semiconductor layer 44 penetrates the word line conductive layers 41a˜41q. The columnar semiconductor layer 44 extends in a direction substantively perpendicular to the semiconductor substrate 20. A pair of the columnar semiconductor layers 44 are formed continuously in an integrated manner with the previously mentioned semiconductor layer 33. The pair of columnar semiconductor layers 44 are aligned in a vicinity of ends in the column direction of the semiconductor layer 33. The columnar semiconductor layer 44 is configured by polysilicon (poly-Si).

In the above-described back gate layer 30 and memory layer 40, the pair of columnar semiconductor layers 44 and the semiconductor layer 33 joining lower ends of the pair of columnar semiconductor layers 44 configure a memory semiconductor layer 44A that functions as a body (channel) of the memory string MS. The memory semiconductor layer 44A is formed in a U shape viewed from the row direction.

Expressing the above-described configuration of the memory layer 40 in other words, the word line conductive layers 41a˜41q surround the side surface of the columnar semiconductor layer 44 via the memory gate insulating layer 43.

As shown in FIGS. 3 and 4, the select transistor layer 50 includes a source side conductive layer 51a and a drain side conductive layer 51b. The source side conductive layer 51a functions as the source side select gate line SGS and the gate of the source side select transistor SSTr. The drain side conductive layer 51b functions as the drain side select gate line SGD and the gate of the drain side select transistor SDTr.

The source side conductive layer 51a is formed in a layer above one of the columnar semiconductor layers 44 configuring the memory semiconductor layer 44A. The drain side conductive layer 51b is formed in the same layer as the source side conductive layer 51a in a layer above the other of the columnar semiconductor layers 44 configuring the memory semiconductor layer 44A. A plurality of the source side conductive layers 51a and drain side conductive layers 51b extend in the row direction with a certain pitch in the column direction. The source side conductive layer 51a and the drain side conductive layer 51b are configured by, for example, polysilicon (poly-Si).

As shown in FIG. 4, the select transistor layer 50 includes a source side gate insulating layer 52a, a source side columnar semiconductor layer 53a, a drain side gate insulating layer 52b, and a drain side columnar semiconductor layer 53b. The source side columnar semiconductor layer 53a functions as a body (channel) of the source side select transistor SSTr. The drain side columnar semiconductor layer 53b functions as a body (channel) of the drain side select transistor SDTr.

The source side gate insulating layer 52a contacts a side surface of the source side conductive layer 51a. The source side gate insulating layer 52a is configured by, for example, silicon oxide (SiO₂).

The source side columnar semiconductor layer 53a, along with the source side conductive layer 51a, sandwiches the source side gate insulating layer 52a. The source side columnar semiconductor layer 53a penetrates the source side conductive layer 51a. The source side columnar semiconductor layer 53a is connected to an upper surface of one of the pair of columnar semiconductor layers 44 and formed in a column shape extending in a direction substantively perpendicular to the semiconductor substrate 20. The source side polysilicon (poly-Si).

The drain side gate insulating layer 52b contacts a side surface of the drain side conductive layer 51b. The drain side gate insulating layer 52b is configured by, for example, silicon oxide (SiO₂).

The drain side columnar semiconductor layer 53b, along with the drain side conductive layer 51b, sandwiches the drain side gate insulating layer 52b. The drain side columnar semiconductor layer 53b penetrates the drain side conductive layer 51b. The drain side columnar semiconductor layer 53b is connected to an upper surface of one of the pair of columnar semiconductor layers 44 and formed in a column shape extending in a direction substantively perpendicular to the semiconductor substrate 20. The drain side columnar semiconductor layer 53b is configured by polysilicon (poly-Si).

Expressing the above-described configuration of the select transistor layer 50 in other words, the source side conductive layer 51a surrounds a side surface of the source side columnar semiconductor layer 53a via the source side gate insulating layer 52a. The drain side conductive layer 51b surrounds a side surface of the drain side columnar semiconductor layer 53b via the drain side gate insulating layer 52b.

The wiring layer 60 includes a source line layer 61, a bit line layer 62, and a plug layer 63. The source line layer 61 functions as the source line SL. The bit line layer 62 functions as the bit line BL.

The source line layer 61 extends in the row direction contacting an upper surface of the source side columnar semiconductor layer 53a. The bit line layer 62 extends in the column direction contacting an upper surface of the drain side columnar semiconductor layer 53b via the plug layer 63. The source line layer 61, the bit line layer 62, and the plug layer 63 are configured by, for example, a metal such as tungsten.

Next, a configuration of a word line contact formation portion 70 located in a periphery of the memory block MB is described with reference to FIG. 4. The word line contact formation portion 70 is a portion for forming ends of the back gate conductive layer 31, the word line conductive layers 41a˜41q, the source side conductive layer 51a, and the drain side conductive layer 51b in a stepped shape, and connecting these conductive layers to contacts 71a-71r.

That is, as shown in FIG. 4, the back gate conductive layer 31 and the word line conductive layers 41a˜41q configure a stepped portion ST formed in a stepped shape such that positions of ends in the row direction of the back gate conductive layer 31 and the word line conductive layers 41a˜41q differ. The stepped portion ST includes steps ST(0)˜ST (17) arranged in a line in the row direction. As shown in FIG. 4, the steps ST(0)˜ST (17) are arranged from a lower layer to an upper layer. Illustrated here is the case shown in FIG. 4 where the steps ST(0)˜ST(17) are aligned only in the column direction, but a configuration may also be adopted where the steps are formed in a matrix (two-dimensionally), like a contact formation portion CN of a capacitor CAP described later.

The contacts 71a-71r are formed on upper surfaces of the steps ST(0)˜ST(17). The contact 71a contacts the upper surface of the back gate conductive layer 31 (step ST(0)). In addition, the contacts 71b˜71r contact the upper surfaces of the word line conductive layers 41a˜41q (steps ST(1)˜ST(17)), respectively. Provided on upper surfaces of the contacts 71a-71r are lead out lines 72 each extending in a direction parallel to the semiconductor substrate 20. Note that although not illustrated in FIG. 4, similar contacts are formed also on upper surfaces of the source side conductive layer 51a and the drain side conductive layer 51b.

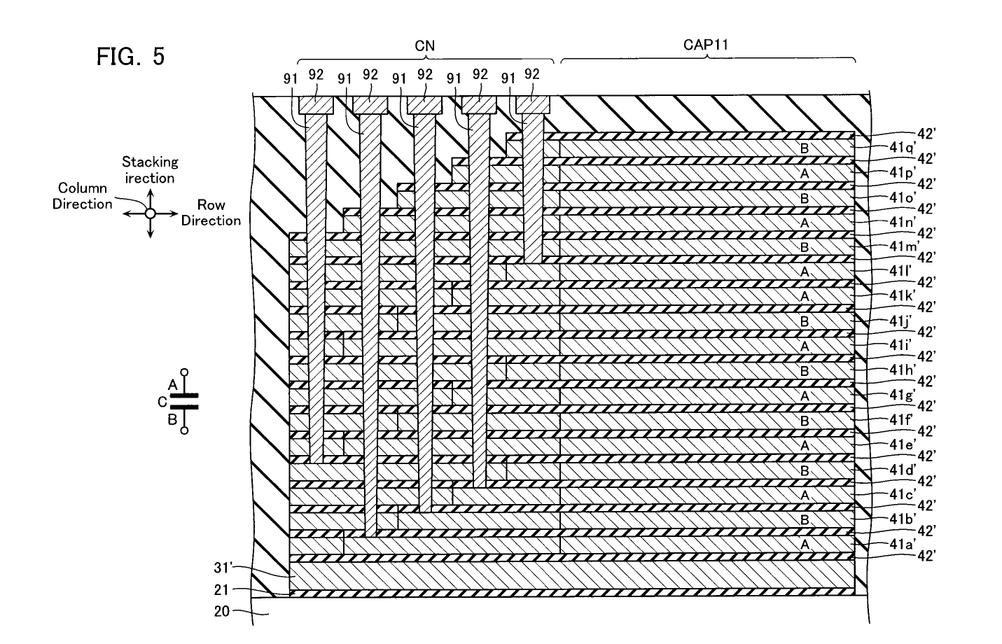

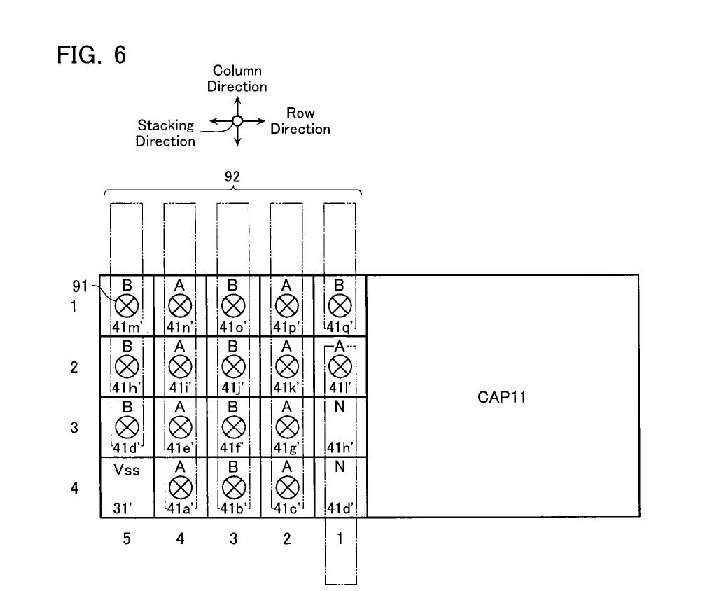

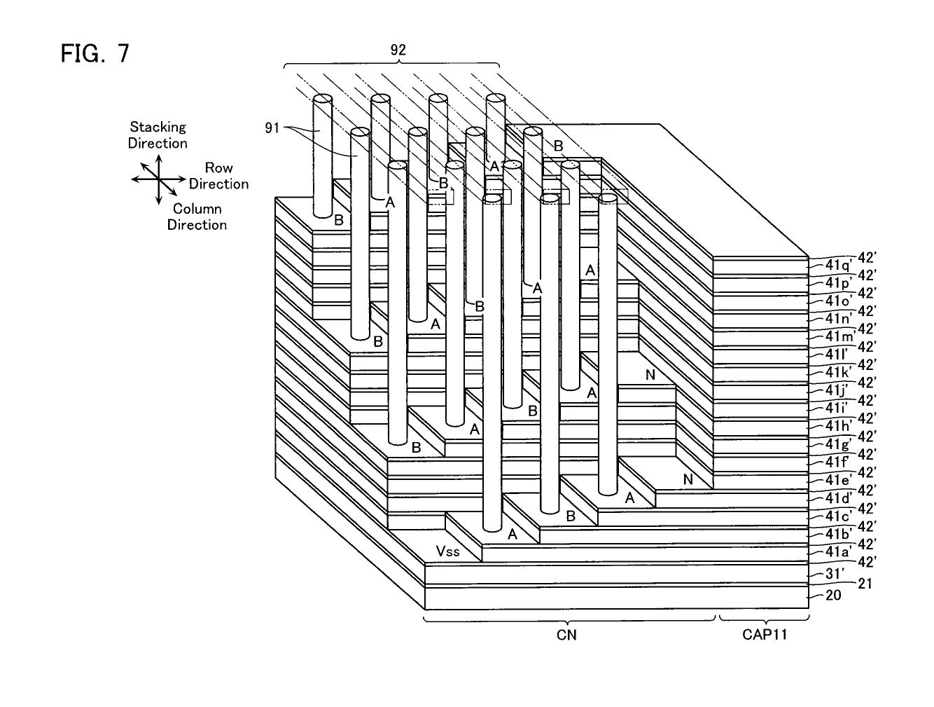

Next, a specific structure of a capacitor CAP11 and the contact formation portion CN are described with reference to FIGS. 5˜7. FIG. 5 is an elevation view of the capacitor CAP11 and the contact formation portion CN connected to the capacitor CAP11. FIG. 6 is a plan view of the capacitor CAP11 and the contact formation portion CN and shows a relationship of connection between a contact 91 and wiring portion 92 and the contact formation portion CN. FIG. 7 is a perspective view of the capacitor CAP11 and the contact formation portion CN.

The capacitor CAP11 functions as a capacitor included in various kinds of peripheral circuits (for example, the boost circuit 16) formed surrounding the memory cell array 11. In addition, the contact formation portion CN is a region for forming a contact for electrically connecting this capacitor CAP11. That is, the capacitor CAP11 and the contact formation portion CN form a single capacitor C. As shown in FIG. 5, the capacitor CAP11 comprises an interlayer insulating film 21′ formed on the semiconductor substrate 20, a conductive layer 31′, conductive layers 41a′˜41q′, and an interlayer insulating layer 42′. The interlayer insulating film 21′ and the conductive layer 31′ are formed in identical layers by identical materials to the interlayer insulating film 21 and the back gate conductive layer 31 shown in FIG. 4.

Moreover, the conductive layers 41a′˜41q′ and the interlayer insulating layer 42′ are formed in a further upper layer above the conductive layer 31′. The conductive layers 41a′˜41q′ and the interlayer insulating layer 42′ are formed in identical layers by identical materials to the conductive layers 41a˜41q and the interlayer insulating layer 42 shown in FIG. 4.

Furthermore, the conductive layers 41a′˜41q′ each function as either a first electrode A or a second electrode B of the capacitor C. In this example in FIG. 5, an electrode functioning as the first electrode A and an electrode functioning as the second electrode B are stacked alternately. This results in a capacitive element being formed respectively between the conductive layers 41a′˜41q′, whereby capacitance of the capacitor C can be increased. However, the conductive layer 41k′ and conductive layer 41l′ that are adjacent to each other both function as the first electrode A. That is, electrodes functioning as the first electrode A are stacked consecutively. The reason for this is mentioned later.

The contact formation portion CN has ends of the conductive layers 41a′˜41q′ formed as a matrix of steps (two-dimensionally formed steps). This enables the conductive layers 41a′˜41q′ and the wiring line portion 92 to be connected via the contact 91.

As shown in FIGS. 6 and 7, the contact formation portion CN includes a stepped portion formed in a matrix (two-dimensionally) in the row direction and the column direction.

As previously mentioned, the capacitor CAP11 in this embodiment comprises 17 layers of (word line) conductive layers 41a′˜41q′ and one layer of the conductive layer 31′ (total of 18 conductive layers). In order to connect these 18 layers of conductive layers to the contacts 91, the contact formation portion CN includes a 5 column by 4 row (=20 step) matrix of steps (in two dimensions).

Furthermore, as shown in FIG. 6, the contact formation portion CN in the present embodiment is formed such that steps connected to the first electrode A are arranged in a line in the column direction and steps connected to the second electrode B are arranged in a line in the column direction. For example, the second column of steps in the matrix has steps connected to the first electrode A arranged in a line. The third column has steps connected to the second electrode B arranged in a line. The fourth column has steps connected to the first electrode A arranged in a line. The fifth column too, excluding the conductive layer 31′ in a lowermost layer, has steps connected to the second electrode B arranged in a line. However, in the first column, steps connected to the first electrode A and steps connected to the second electrode B are mixed, and, moreover, steps N1 and N2 used for neither are also present. The step N1 has a height identical to that of the conductive layer 41h′, that is, the step in the second row and fifth column. The step N2 has a height identical to that of the conductive layer 41d′, that is, the step in the third row and fifth column.

As described above, in the present embodiment, the capacitor CAP11 includes a contact formation portion CN that includes a matrix of steps, and, moreover, the steps connected to an identical electrode (A or B) are arranged in a line in the column direction and may be connected to a single wiring line portion 92. Therefore, exclusive area of the contact formation portion CN can be reduced. Note that the wiring line portion 92 is connected directly (physically) to the contact 91 in FIG. 5, but the wiring line portion 92 and the contact 91 may also be connected via a separate wiring line or the like. That is, the wiring line portion 92 and the contact 91 need only be electrically connected by some means or other.

Reducing an area ratio of the contact formation portion CN with respect to the capacitor CAP11, as well as gaining the advantage of reducing exclusive area, contributes also to an improvement in performance of the capacitor CAP11 itself. That is, the area of the contact formation portion CN getting smaller enables parasitic resistance of the capacitor CAP to be reduced, whereby power consumption can be reduced.

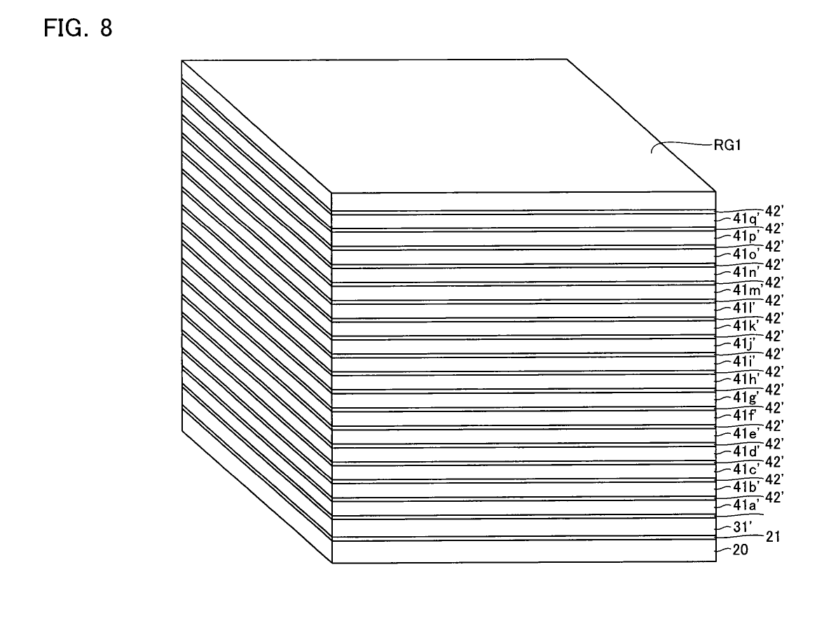

Next, a method of manufacturing the capacitor CAP11 and the contact formation portion CN is described with reference to FIGS. 8˜10. First, as shown in FIG. 8, the conductive layer 31′, the conductive layers 41a′˜41q′, and the interlayer insulating layers 42′ are deposited on the semiconductor substrate 20, via the interlayer insulating film 21. Then, a resist RG1 is deposited in a layer above an uppermost layer of the interlayer insulating films 42′.

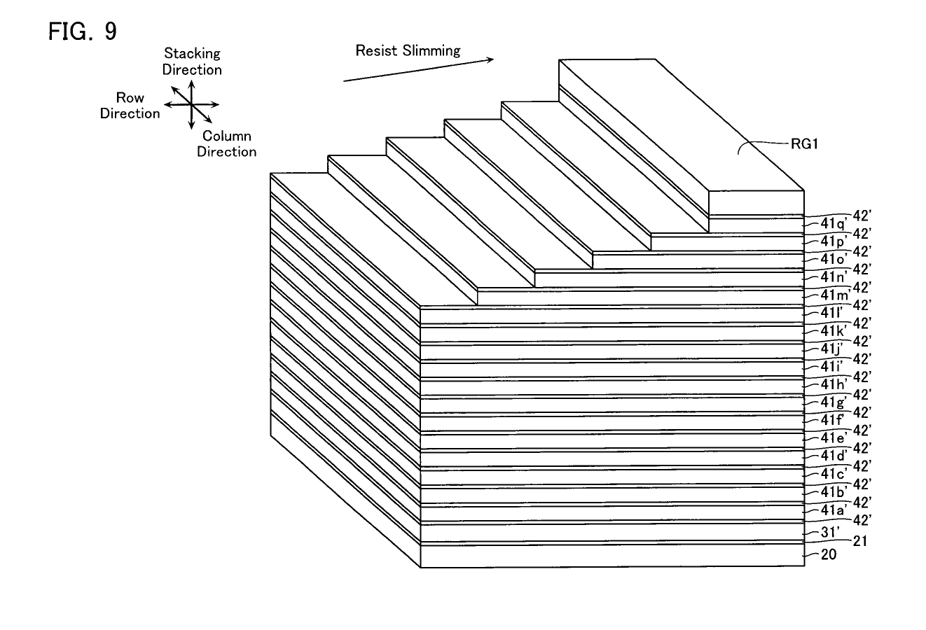

Next, as shown in FIG. 9, dry etching of the conductive films 41a′˜41q′ and the interlayer insulating films 42′ is executed while gradually removing the resist RG1 by slimming. This results in the conductive films 41a′˜41q′ and the interlayer insulating films 42′ changing into steps having a height that changes incrementally in the row direction. Slimming is disclosed in, for example, U.S. patent application Ser. No. 13/156,602 relating to a nonvolatile semiconductor memory, filed on Jun. 9, 2011, the entire contents of which are incorporated in the present application.

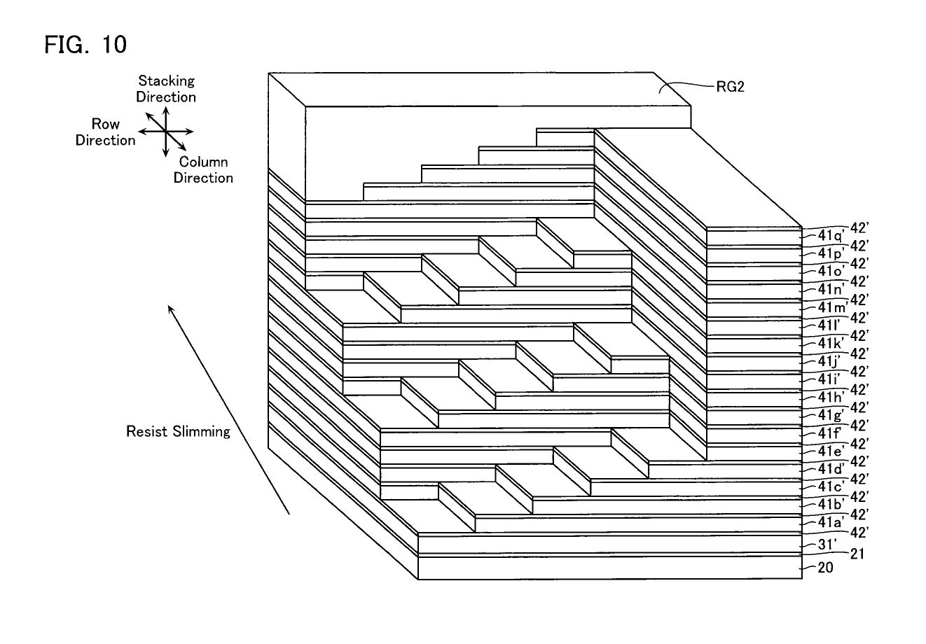

Then, after this resist RG1 has been peeled off, a further resist RG2 is formed covering the capacitor CAP11 and the contact formation portion CN. Then, as shown in FIG. 10, dry etching of the conductive films 41a′˜41q′ and the interlayer insulating films 42′ is executed while gradually removing the resist RG2 by slimming, in the contact formation portion CN. This results in the conductive films 41a′˜41q′ and the interlayer insulating films 42′ changing into steps having a height that changes incrementally not only in the row direction but also in the column direction (that is, results in the films changing into a matrix of steps).

### Advantages

As described above, the nonvolatile semiconductor memory device according to the first embodiment results in the contact formation portion CN of the capacitor CAP11 being formed in a matrix of steps, and, moreover, results in steps linking conductive layers that function as one electrode being formed in a line. Therefore, exclusive area of the contact formation portion CN can be reduced, whereby area of the nonvolatile semiconductor memory device overall can be reduced. Moreover, reducing area ratio of the contact formation portion CN with respect to the capacitor CAP11 enables performance of the capacitor CAP itself to be improved. Furthermore, the number of wiring line portions 92 connected to the contact formation portion CN can be reduced, hence parasitic resistance can be lowered.

Note that in the explanation of the above-described embodiment, a reduction in exclusive area of the contact formation portion CN is achieved by having the wiring line portion 92 extending having the column direction as a long direction, and being formed such that steps connected to an identical electrode B in the contact formation portion CN are arranged in a line in the column direction. However, instead of this, it is also possible to have the wiring line portion 92 extending having the row direction as a long direction and being formed such that steps connected to an identical electrode in the contact formation portion CN are arranged in a line in the row direction. This also enables a reduction in exclusive area of the contact formation portion CN to be achieved.

### Second Embodiment

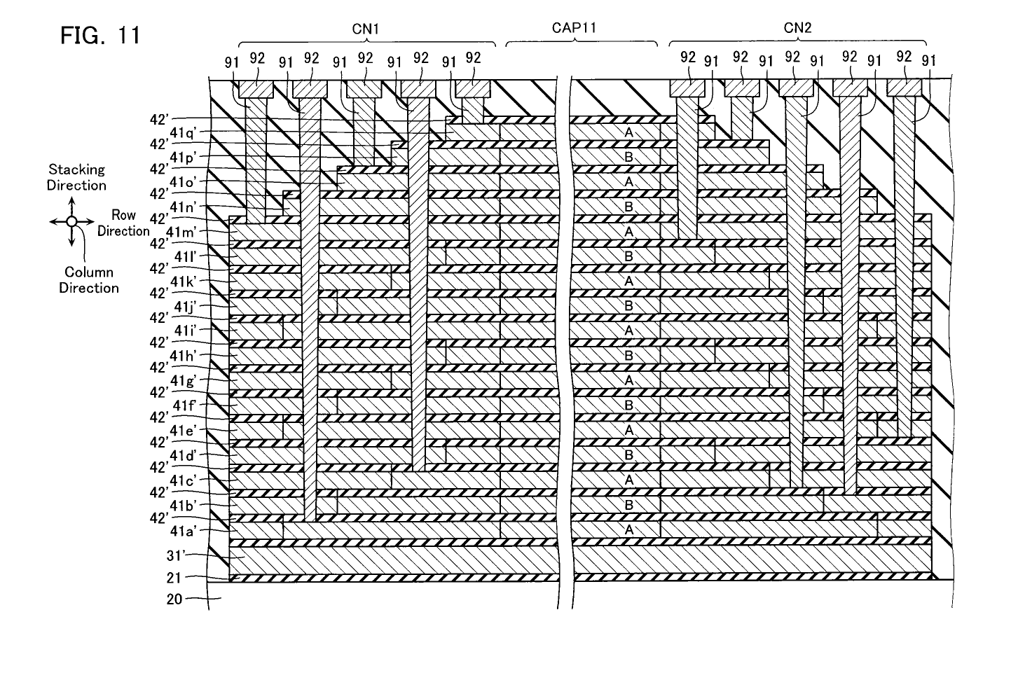

Next, a nonvolatile semiconductor memory device according to a second embodiment is described with reference to FIGS. 11-13. A structure of the nonvolatile semiconductor memory device in this second embodiment is similar to that of the first embodiment (FIGS. 1˜4), apart from a structure of the capacitor CAP11 and the contact formation portion CN.

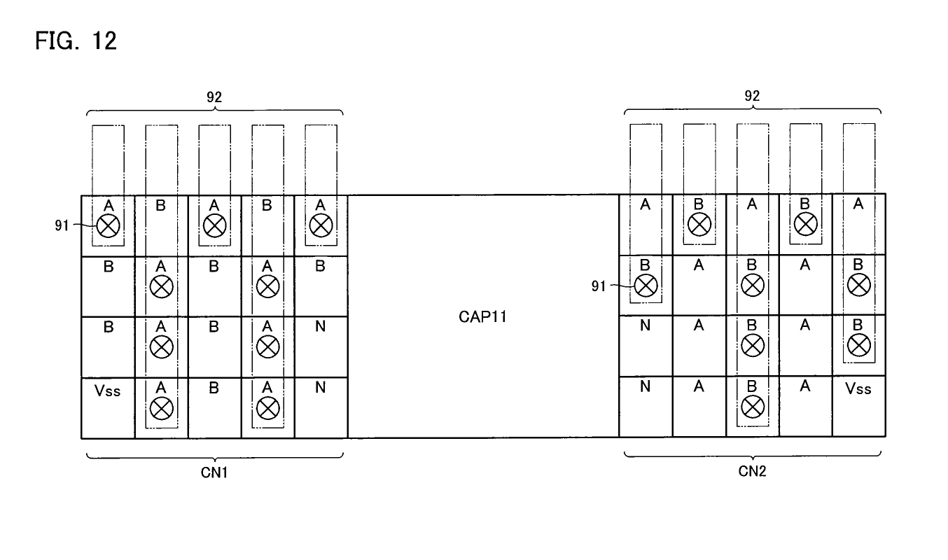

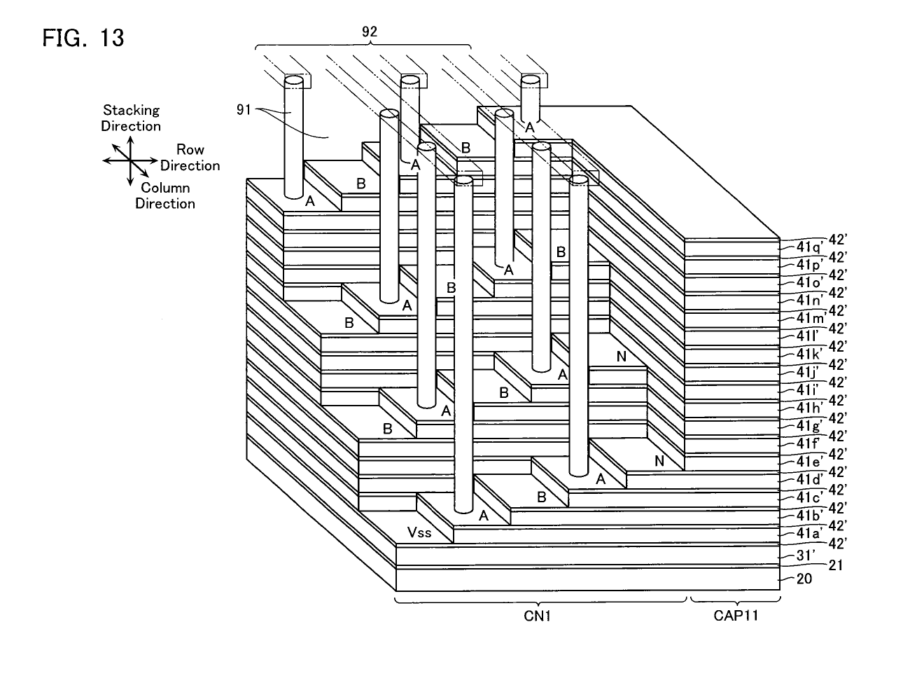

The capacitor CAP11 in the first embodiment included the contact formation portion CN only on one side thereof. In contrast, as shown in FIG. 11, the capacitor CAP11 in the second embodiment includes two contact formation portions CN1 and CN2 at two opposing sides. Moreover, as shown in FIGS. 12 and 13, the contact formation portion CN1 is connected only to electrode layers 41a′˜41q′ that are to become the first electrode A. On the other hand, the contact formation portion CN2 is connected only to electrode layers 41a′˜41q′ that are to become the second electrode B.

Note that in the first embodiment, in order to configure such that steps of conductive layers 41a′˜41q′ connected to an identical electrode (A or B) are arranged in a line in the column direction, the conductive layer 41k′ and 41l′ adjacent to each other were both connected to the first electrode A. In contrast, in the second embodiment, one capacitor CAP11 includes two contact formation portions CN1 and CN2. As a result, there is no need for steps of conductive layers 41a′˜41q′ connected to an identical electrode to be arranged in a line in the column direction.

That is, as shown in FIG. 11, the capacitor CAP11 in the second embodiment adopts a configuration in which the first electrodes A and the second electrodes B are all ( . . . are strictly) formed alternately. For example, there are no places where the first electrodes A are adjacent to each other. The same applies also to the second electrodes B. This structure of the capacitor CAP11 enables capacitance of the capacitor CAP11 to be increased compared to a structure in the first embodiment. Note that a configuration of the capacitor CAP11 similar to that in the first embodiment may be adopted also in the second embodiment.

### Third Embodiment

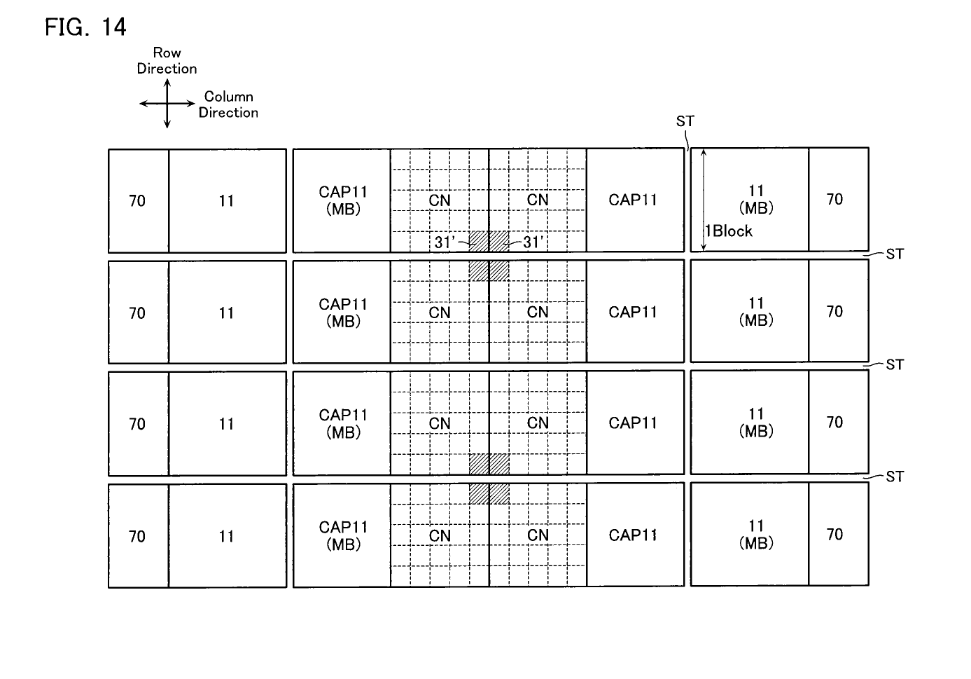

Next, a configuration of a nonvolatile semiconductor memory device according to a third embodiment is described with reference to FIG. 14. A structure of the nonvolatile semi conduct or memory device in this third embodiment has a feature in a layout of the memory cell array 11, a contact formation portion 70, the capacitor CAP11, and the contact formation portion CN. In other respects, the structure is similar to that of the first embodiment (FIGS. 1˜4).

As shown in FIG. 14, in this third embodiment, the memory blocks MB (one block being a smallest unit of a data erase operation) are disposed in a matrix. Each memory block MB is separated by a slit ST, the slit ST being filled with an interlayer insulating film not illustrated. Moreover, a contact formation portion 70 is formed in each of the memory blocks MB adjacently to the memory block MB.

In addition, a plurality of capacitors CAP11 and contact formation portions CN are disposed in a matrix, adjacently to the memory block MB. The capacitors CAP11 are also separated into one block units by the slit ST.

At the same time, four contact formation portions CN for four capacitors CAP11 disposed in a matrix are disposed in a matrix and adjacently to each other. Moreover, the four contact formation portions CN disposed facing each other in a matrix are disposed having steps in a lowermost layer (part shown by hatching: conductive layer 31′) adjacent to each other. In other words, a layout is adopted such that valley portions of the four contact formation portions CN are adjacent to each other and the four contact formation portions have, so to speak, a bowl shape. This structure allows the wiring line portion 92 to be shared by a portion of the plurality of contact formation portions CN, thereby enabling a reduction in wiring line resistance to be achieved.

### Fourth Embodiment

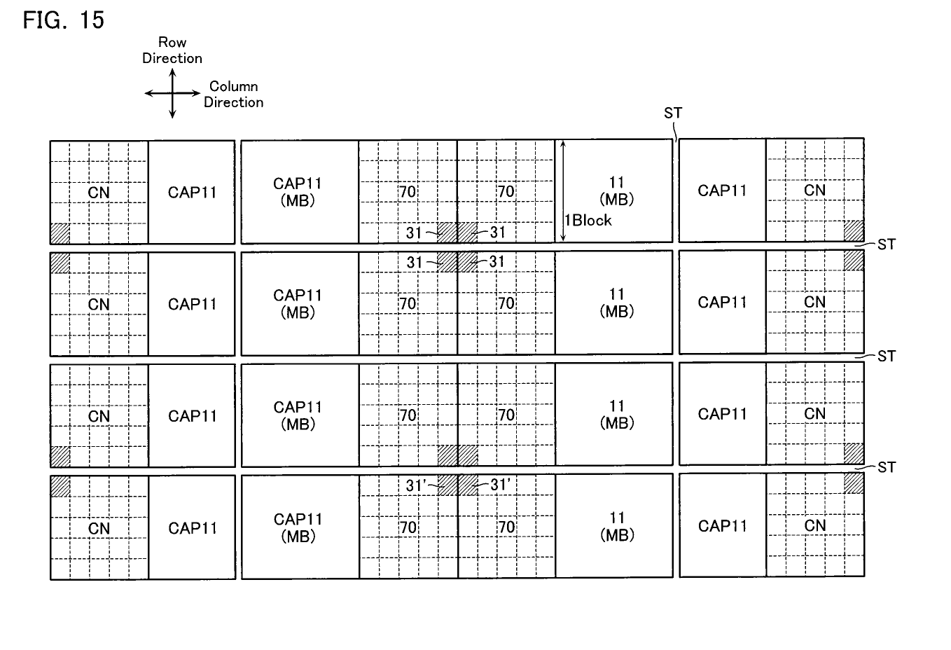

Next, a configuration of a nonvolatile semiconductor memory device according to a fourth embodiment is described with reference to FIG. 15. A structure of the nonvolatile semiconductor memory device in this fourth embodiment has a feature in a structure of the contact formation portion 70 of the memory cell array 11. Furthermore, this fourth embodiment has a feature in a layout of the memory cell array 11, the contact formation portion 70, the capacitor CAP11, and the contact formation portion CN. In other respects, the fourth embodiment is similar to the first embodiment (FIGS. 1˜4).

The fourth embodiment differs from the first embodiment in that in this fourth embodiment, the contact formation portion 70 in the memory cell array 11 comprises steps in a matrix (in two dimensions) similarly to the contact formation portion CN.

Moreover, two memory cell arrays 11 and two contact formation portions 70 are disposed line-symmetrically in the column direction. Further, the two contact formation portions 70 disposed facing each other are disposed having steps in a lowermost layer (conductive layer 31) adjacent to each other.

### Fifth Embodiment

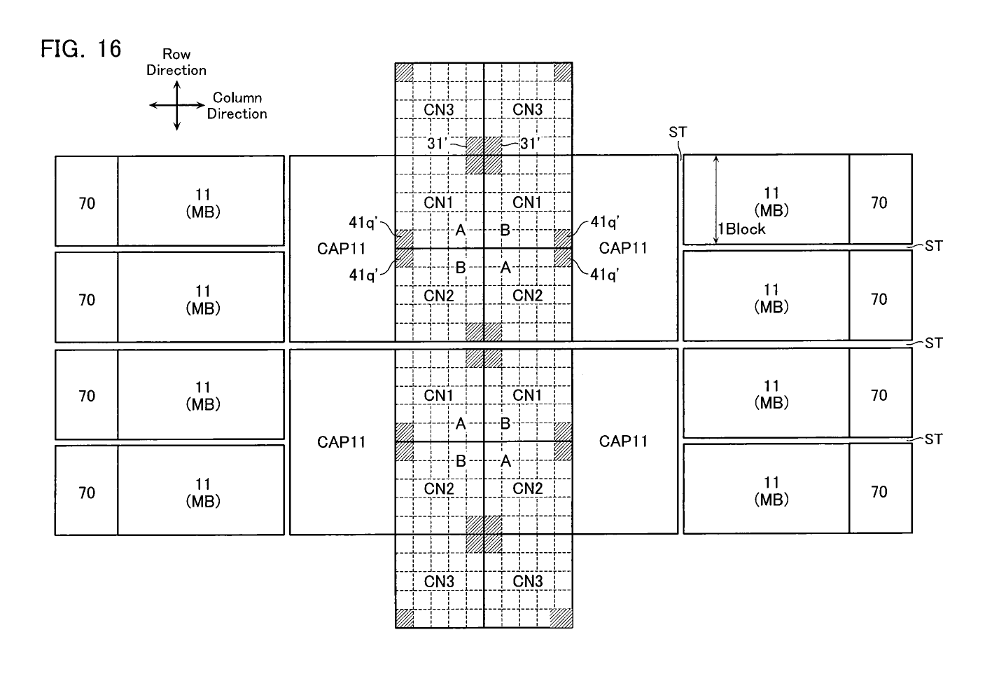

Next, a configuration of a nonvolatile semiconductor memory device according to a fifth embodiment is described with reference to FIG. 16. A structure of the nonvolatile semiconductor memory device in this fifth embodiment has a feature in a layout of the memory cell array 11, the contact formation portion 70, the capacitor CAP11, and the contact formation portion CN. In other respects, the structure is similar to that of the first embodiment (FIGS. 1˜4).

The capacitor CAP11 in this embodiment is shared by two memory blocks MB. In other words, the capacitor CAP11 in the present embodiment has a size which is two blocks' worth. Moreover, this capacitor CAP11 comprises contact formation portions CN1 and CN2 on a side surface which is on an opposite side to the memory blocks MB. The contact formation portion CN1 is a region for connecting to the contact 91 steps connected to the first electrode A, and the contact formation portion CN2 is a region for connecting to the contact 91 steps connected to the second electrode B.

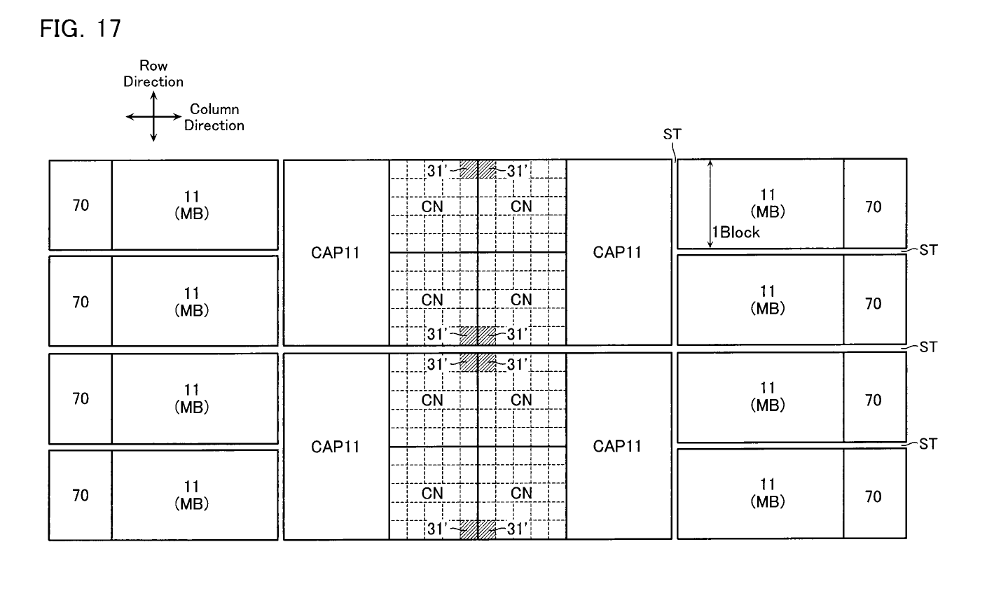

In this embodiment, the contact formation portions CN1 and CN2 are formed such that fellow steps of the matrix of steps (20 steps) that are in a highest position (steps shown by double hatching in FIG. 16 (conductive layer 41q′)) are adjacent (in other words, mountain portions are shared). This configuration allows parasitic resistance in a capacitive element to be reduced compared to in the third embodiment (FIG. 14). This is because the mountain portion being shared results in area of the wiring line portion being increased compared to the case of FIG. 14. Note that in the present embodiment, a dummy contact formation region CN3 is formed for reasons related to manufacturing processes, but it is of course also possible to adopt a configuration as in FIG. 17 by removing the dummy contact formation portion CN3 in a later process.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

Structure of the memory cell array 11 is not limited as above description. A memory cell array formation may be disclosed in U.S. patent application Ser. No. 12/532,030 filed on Mar. 23, 2009. U.S. patent application Ser. No. 12/532,030, the entire contents of which are incorporated by reference herein.

Furthermore A memory cell array formation may be disclosed in U.S. patent application Ser. No. 12/679,991 filed on Mar. 25, 2010. U.S. patent application Ser. No. 13/236,734, the entire contents of which are incorporated by reference herein.

What is claimed is:

1. A nonvolatile semiconductor memory device, comprising:
a semiconductor substrate;
a memory cell array including a plurality of memory cells stacked; and
a capacitor including:
a first conductive layer functioning as a first electrode, the first conductive layer including a first portion;
a second conductive layer functioning as the first electrode, the second conductive layer including a second portion, the second portion and the first portion being arranged in a first direction parallel to the semiconductor substrate;
a third conductive layer functioning as a second electrode, the third conductive layer including a third portion; and
a fourth conductive layer functioning as the second electrode, the fourth conductive layer including a fourth portion, the fourth portion and the third portion being arranged in the first direction, both the fourth portion and the third portion being arranged in a second direction away from both the second portion and the first portion, the second direction being parallel to the semiconductor substrate and being orthogonal to the first direction;
a first contact connected to the first portion;
a second contact connected to the second portion;
a third contact connected to the third portion; and
a fourth contact connected to the fourth portion.

2. The nonvolatile semiconductor memory device according to claim 1, wherein ends of the first conductive layer to the fourth conductive layer are formed in a stepped shape.

3. The nonvolatile semiconductor memory device according to claim 2, wherein
the first conductive layer is adjacent to the third conductive layer in a lamination direction of the semiconductor substrate.

4. The nonvolatile semiconductor memory device according to claim 1, wherein
a wiring line portion connected to the first electrode via the first and second contacts and a wiring line portion connected to the second electrode via the third and fourth contacts are disposed alternately along the second direction.

5. The nonvolatile semiconductor memory device according to claim 1, wherein
the second direction is a direction in which the first conductive layer, the second conductive layer, the third conductive layer, and the fourth conductive layer extend.

6. A nonvolatile semiconductor memory device, comprising:
a semiconductor substrate;
a memory cell array provided above the semiconductor substrate and configured having memory transistors arranged three-dimensionally therein; and
a capacitor provided above the semiconductor substrate,
the capacitor comprising:
a plurality of first conductive layers formed on the semiconductor substrate and functioning as a first electrode and a second electrode of the capacitor;
a contact formation portion configured having ends of the plurality of first conductive layers formed in a stepped shape, the stepped shape being arranged in a matrix in a first direction and a second direction, the second direction being orthogonal to the first direction;
a contact formed extending from the contact formation portion; and
a wiring line portion connected to the contact and extending with the first direction as a long direction,
the contact formation portion being formed such that the first conductive layer functioning as the first electrode is aligned in the first direction, and being formed such that the first conductive layer functioning as the second electrode is aligned in the first direction.

7. The nonvolatile semiconductor memory device according to claim 6, wherein
of the plurality of first conductive layers, at least one pair of the first conductive layers that function as either the first electrode or the second electrode are adjacent to each other in a stacking direction.

8. The nonvolatile semiconductor memory device according to claim 6, wherein
several of stepped portions arranged in a matrix in the contact formation portion have an identical height, and
one of the stepped portions that have the identical height is connected to the contact, and the other of the stepped portions is not connected to the contact.

9. The nonvolatile semiconductor memory device according to claim 8, wherein
of the plurality of first conductive layers, at least one pair of the first conductive layers that function as either the first electrode or the second electrode are adjacent to each other in a stacking direction.

10. The nonvolatile semiconductor memory device according to claim 6, wherein
the wiring line portion connected to the first electrode and the wiring line portion connected to the second electrode are disposed alternately along the second direction.

11. The nonvolatile semiconductor memory device according to claim 6, wherein
a plurality of the contact formation portions are formed adjacently, and
the plurality of the contact formation portions that are adjacent are formed such that lowermost stepped portions which are the lowest among the stepped portions formed in a matrix are adjacent to each other.

12. The nonvolatile semiconductor memory device according to claim 11, wherein
of the plurality of first conductive layers, at least one pair of the first conductive layers that function as either the first electrode or the second electrode are adjacent to each other in a stacking direction.

13. The nonvolatile semiconductor memory device according to claim 6, wherein
the memory cell array comprises:
a plurality of second conductive layers stacked on the semiconductor substrate so as to sandwich an interlayer insulating film and functioning as a gate of the memory transistor;
a memory gate insulating layer contacting a side surface of the second conductive layer; and
a semiconductor layer formed so as to sandwich the memory gate insulating layer with the plurality of second conductive layers, extending in a substantively perpendicular direction to the semiconductor substrate, and functioning as a body of the memory transistor, and
the first conductive layers and the second conductive layers are formed in an identical layer in the stacking direction.

14. The nonvolatile semiconductor memory device according to claim 1, wherein
the memory cell array includes a plurality of memory blocks arranged in a matrix,
each of the memory blocks includes a contact formation portion arranged adjacent thereto,
the contact formation portions are arranged in a matrix.

15. The nonvolatile semiconductor memory device according to claim 14, wherein
the contact formation portions arranged in a matrix are arranged such that steps in a lowermost layer are adjacent to each other.

16. The nonvolatile semiconductor memory device according to claim 13, wherein
the contact formation portions arranged in a matrix are arranged such that steps in a highest layer are adjacent to each other.

17. A nonvolatile semiconductor memory device, comprising:
a semiconductor substrate;
a memory cell array provided on the semiconductor substrate and configured having memory transistors arranged three-dimensionally therein; and
a capacitor provided on the semiconductor substrate,
the capacitor comprising:
a plurality of conductive layers formed on the semiconductor substrate and functioning as a first electrode and a second electrode of the capacitor;
a contact formation portion configured having ends of the plurality of conductive layers formed in a stepped shape, the stepped shape being arranged in a matrix in a first direction and a second direction, the second direction being orthogonal to the first direction;
a contact formed extending from the contact formation portion; and
a wiring line portion connected to the contact and extending with the first direction as a long direction,
the contact formation portion comprising: a first contact formation portion which is on a first side of the capacitor; and a second contact formation portion which is on a second side of the capacitor,
in the first contact formation portion, the conductive layer that functions as the first electrode being connected to the wiring line portion via the contact, and
in the second contact formation portion, the conductive layer that functions as the second electrode being connected to the wiring line portion via the contact.

18. The nonvolatile semiconductor memory device according to claim 17, wherein
a plurality of the contact formation portions are formed adjacently, and
the plurality of the contact formation portions that are adjacent are formed such that lowermost stepped portions which are the lowest among the stepped portions formed in a matrix are adjacent to each other.

19. The nonvolatile semiconductor memory device according to claim 17, wherein
several of stepped portions arranged in a matrix in the contact formation portion have an identical height, and
one of the stepped portions that have the identical height is connected to the contact, and the other of the stepped portions is not connected to the contact.

20. The nonvolatile semiconductor memory device according to claim 17, wherein
the memory cell array comprises:
a plurality of second conductive layers stacked on the semiconductor substrate so as to sandwich an interlayer insulating film and functioning as a gate of the memory transistor;
a memory gate insulating layer contacting a side surface of the second conductive layer; and
a semiconductor layer formed so as to sandwich the plurality of second conductive layers along with the memory gate insulating layer, extending in a substantively perpendicular direction to the semiconductor substrate, and functioning as a body of the memory transistor, and
the first conductive layer and the second conductive layer are formed in an identical layer in the stacking direction.
